(19) United States
(12) Patent Application Publication
(10) Pub. No.: US 2025/0102635 A1
(43) Pub. Date: Mar. 27, 2025

(54) DETECTOR HAVING FRONT-SIDE AND REAR-SIDE ILLUMINATION, LIDAR MODULE HAVING SUCH A DETECTOR, AND METHOD FOR OPERATING THE LIDAR MODULE

(71) Applicant: ams-OSRAM International GMBH, Regensburg (DE)

(72) Inventors: Reiner WINDISCH, Pettendorf (DE); Hubert HALBRITTER, Dietfurt (DE); Simon LANKES, Regensburg (DE)

(21) Appl. No.: 18/730,334

(22) PCT Filed: Dec. 20, 2022
(86) PCT No.: PCT/EP2022/087025

§ 371 Date: Jul. 19, 2024

(30) Foreign Application Priority Data
Jan. 19, 2022 (DE) 10 2022 101 149.6

(51) Int. Cl. G01S 7/481; G01S 17/32

(52) U.S. Cl. CPC G01S 7/4816; G01S 7/4814; G01S 17/32

(57) ABSTRACT

A detector is provided which includes at least the following features:
a substrate; and
at least a first detector element and a second detector element, which are arranged laterally next to one another on a main surface of the substrate, wherein
each of the detector elements includes an active semiconductor layer configured for converting electromagnetic radiation having a wavelength λ into an electrical signal,
each of the detector elements includes a first main surface and a second main surface opposite the first main surface, and
the first main surface and the second main surface are each configured for coupling in and for coupling out electromagnetic radiation of wavelength λ.

Furthermore, a lidar module and a method for operating a lidar module are specified.

### CROSS-REFERENCE TO RELATED APPLICATIONS

This application is a 371 U.S. National Phase of PCT International Patent Application No. PCT/EP2022/087025, filed on Dec. 20, 2022, which claims priority from German Patent Application No. 10 2022 101 149.6, filed on Jan. 19, 2022, the disclosures of which are incorporated by reference herein in their entirety for all purposes.

### TECHNICAL FIELD

The present disclosure relates to detectors, and in particular, detectors for a LIDAR module.

### BRIEF SUMMARY

A detector, a lidar module and a method for operating a lidar module are specified.

An object of at least certain embodiments is to provide a detector for improved differential detection of frequency modulated continuous wave lidar (FMCW lidar) signals.

According to at least one embodiment, the detector includes a substrate. The substrate includes, for example, a semiconductor material, e.g., silicon. In particular, the substrate is configured for mechanically stabilizing the detector. This means that the substrate may be one or the mechanically load-bearing component of the detector.

Furthermore, the substrate may include integrated electronic circuits. For example, an evaluation unit or part of an evaluation unit of the detector is integrated in the substrate as an electronic circuit.

According to at least one further embodiment, the detector includes at least a first detector element and a second detector element, which are arranged laterally next to one another on a main surface of the substrate. The main surface of the substrate may correspond to a main extension plane of the substrate, or may run parallel thereto at least in places. Here and in the following, lateral refers to a direction parallel to the main surface of the substrate.

According to at least one further embodiment of the detector, each of the detector elements includes an active semiconductor layer configured for converting electromagnetic radiation into an electrical signal. In particular, the active semiconductor layer is configured for absorbing at least part of the electromagnetic radiation with a wavelength λ incident thereon and convert it into an electric current. For example, the active semiconductor layer includes at least one pn-junction or is part of a Schottky-contact.

The wavelength λ of the electromagnetic radiation may be in the infrared spectral range, for example between 800 nanometers and 1800 nanometers inclusive. A line width of the electromagnetic radiation is, for example, at most 10 megahertz. In some embodiments, a line width of the electromagnetic radiation is, for example, at most 100 kilohertz.

The active semiconductor layer is designed, for example, as a quantum well structure or as a multiple quantum well structure. Here, the term quantum well structure refers in particular to any structure in which charge carriers experience a quantization of their energy states through confinement. In particular, the term quantum well structure does not include any indication of the dimensionality of the quantization. It therefore includes quantum wells, quantum wires and quantum dots and any combination of these structures.

The active semiconductor layer includes, for example, a III-V compound semiconductor material or a IV-IV compound semiconductor material.

A III/V compound semiconductor material includes at least one element from the third main group, such as B, Al, Ga, In, and one element from the fifth main group, such as N, P, As. In particular, the term “III/V compound semiconductor material” includes the group of binary, ternary or quaternary compounds which contain at least one element from the third main group and at least one element from the fifth main group, for example an arsenide compound semiconductor material. Arsenide compound semiconductor materials may include AlₓGa_{y}In_{1-x-y}As, where 0≤x≤1, 0≤y≤1 and x+y≤1. For example, indium gallium arsenide is an arsenide compound semiconductor material with x=0.

A IV/IV compound semiconductor material includes at least two elements from the fourth main group, such as Si, Ge or Sn. For example, silicon germanium Si₁₋ₓGeₓ with 0≤x≤1 is an IV/IV compound semiconductor material.

Such binary, ternary or quaternary compounds may also include, for example, one or more dopants and additional components. The active semiconductor layer may include silicon germanium or indium gallium arsenide, or consists of one of these materials.

According to at least one further embodiment of the detector, each of the detector elements includes a first main surface and a second main surface opposite the first main surface, wherein the first main surface and the second main surface are each configured for coupling in and for coupling out electromagnetic radiation of wavelength λ. The first main surface and the second main surface include, for example, an anti-reflective coating for electromagnetic radiation of wavelength λ. In particular, the anti-reflective coating is configured for minimizing a portion of electromagnetic radiation of wavelength λ that may be reflected when being coupled into the detector elements.

In particular, the detector elements are configured such that during operation of the detector, a transmission signal and a receiving signal are superimposed in counter-propagating directions in the first detector element and in the second detector element. In particular, the transmission signal and the receiving signal include electromagnetic radiation of wavelength λ. For example, a transmission signal is coupled into the detector element via the first main surface, partially absorbed by the active semiconductor layer and coupled out via the second main surface. In this case, the receiving signal is coupled in via the second main surface opposite the first main surface and is at least partially absorbed by the active semiconductor layer. Alternatively, the transmission signal may be coupled in via the second main surface, while the receiving signal is coupled in via the first main surface. In particular, the transmission signal and the receiving signal are superimposed in counter-propagating directions in such a way that a standing electromagnetic wave is formed in the detector elements.

In particular, the first detector element and the second detector element are not identical. For example, the active semiconductor layer in the first detector element is arranged at a different position between the first main surface and the second main surface than in the second detector element. The active semiconductor layers in the two detector elements may be arranged such that the active semiconductor layer in the first detector element is located, for example, at a node of the standing electromagnetic wave, while the active semiconductor layer in the second detector element is located at an anti-node of the standing wave, or vice versa. In other words, a phase difference of the standing electromagnetic wave between the positions of the active semiconductor layers of the first detector element and the second detector element may be an odd multiple of π/2, for example π/2, 3*π/2, or 5*π/2.

The active semiconductor layers in the first detector element and in the second detector element are arranged, in particular, at different positions in the vertical direction. Here, “vertical” refers to a direction perpendicular to the main extension plane of the active semiconductor layers. In other words, the vertical direction is parallel to a growth direction of the semiconductor layers. In particular, the vertical direction denotes a direction perpendicular to the first main surface and/or perpendicular to the second main surface.

According to some embodiments, the detector includes:
a substrate, and
at least a first detector element and a second detector element, which are arranged laterally next to one another on a main surface of the substrate, wherein
each of the detector elements includes an active semiconductor layer configured for converting electromagnetic radiation having a wavelength λ into an electrical signal,
each of the detector elements includes a first main surface and a second main surface opposite the first main surface, and
the first main surface and the second main surface are each configured for coupling in and for coupling out electromagnetic radiation of wavelength λ.

A detector described herein is particularly suitable for differential detection of FMCW lidar signals. The transmission signal, which may include frequency-modulated laser light of wavelength λ in the infrared spectral range, and the receiving signal are superimposed in counter-propagating directions in the first detector element and in the second detector element. The receiving signal includes the transmission signal that is at least partially reflected by an external object.

In particular, the standing electromagnetic wave is formed in the detector elements by the superposition of the transmission signal and the receiving signal in counter-propagating directions. The standing electromagnetic wave includes a wavelength λ/n, where here and in the following n denotes a mean refractive index of a material from which the first detector element and/or the second detector element is formed.

For example, when two linearly polarized, plane electromagnetic waves of the transmission signal and the receiving signal are superimposed in counter-propagating directions with electric field strengths of the form E_{1,2}=E_{1,2}e^{i(k}^{_{1,2}}^{x-ω}^{_{1,2}}^{t)}, wherein E_{1,2} denotes amplitudes, ω_{1,2} denotes frequencies, x denotes a propagation direction and t denotes a time, and wherein the wavenumbers k_{1,2} of the counter-propagating electromagnetic waves are given by

$${k}_{1} = - {k}_{2} = k = \frac{2 π n}{λ} ,$$

an intensity of an electric field in a detector element is given by:

$${\vert {E}_{1} + {E}_{2} \vert}^{2} = {E}_{1}^{2} + {E}_{2}^{2} + 2 {E}_{1} {E}_{2} cos ( 2 kx - ( {ω}_{1} - {ω}_{2} ) t ) .$$

In particular, a phase of the standing electromagnetic wave oscillates with a difference frequency ω₁−ω₂ between the frequency ω₁ of the transmission signal and the frequency ω₂ of the receiving signal as a function of time.

In the case of distance measurement using FMCW lidar, the frequency ω₁ of the transmission signal is increased and/or decreased, in particular linearly, as a function of time. The counter-propagating superposition of the transmission signal and the receiving signal in the detector elements leads to a beating, whereby the difference frequency ω₁−ω₂ between the frequency ω₁ of the transmission signal and the frequency ω₂ of the receiving signal is proportional to a distance between the detector and the external object.

The detector may be configured for measuring the difference frequency ω₁−ω₂ between the transmission signal and the receiving signal. In particular, the detection is differential, whereby an unwanted, time-independent component E₁²+E₂² of the standing electromagnetic wave is eliminated. Differential detection is carried out, in particular, by determining the intensity of the electromagnetic field at two different positions of the standing electromagnetic wave, in particular at one position in the first detector element and at another position in the second detector element.

The active semiconductor layers in the first detector element and in the second detector element may be arranged at a distance of a quarter of the wavelength in the material of the detector elements, i.e. λ/(4*n), in the propagation direction of the standing electromagnetic wave. The photocurrents generated by the active semiconductor layers are proportional to the intensity of the electric field. By subtracting the photocurrents of the two active semiconductor layers of the first detector element and the second detector element at a distance of λ/(4*n), whereby the distance may also be larger by multiples of half the wavelength λ/(2*n), the time-independent component of the standing electromagnetic wave is eliminated, while the component oscillating in time with the difference frequency ω₁−ω₂ is added. Advantageously, this increases a signal-to-noise ratio of the detector. A measurement signal, which results from subtracting the two photocurrents of the two active semiconductor layers, thus exhibits a temporal oscillation with the difference frequency ω₁−ω₂.

In contrast to the detector described here, lidar detectors with a co-propagating superposition of the transmission signal and the receiving signal require, in particular, an optical circulator or separate optics for a transmitter and a receiver. With the detector described here, a single optical system may be used for the transmitter and the receiver, whereby no optical circulator is required. This simplifies the design of the detector. Furthermore, differential detection of the difference frequency improves the signal-to-noise ratio. In particular, unwanted intensity fluctuations that may occur during frequency modulation of the transmission signal are eliminated. With the detector described herein, differential detection is possible with a compact semiconductor component that may be integrated and thus produced cost-effectively.

According to at least one further embodiment, the detector is configured for forming a difference signal between the electrical signal of the first detector element and the electrical signal of the second detector element. In particular, the detector may include an evaluation unit which subtracts the photocurrent of the active layer of the first detector element from the photocurrent of the active layer of the second detector element, or vice versa.

According to at least one further embodiment, the detector may include an evaluation unit. The evaluation unit is configured for forming a difference signal between the electrical signal of the first detector element and the electrical signal of the second detector element. The evaluation unit includes, for example, a differential amplifier and/or an electronic circuit with a transimpedance amplifier, which is configured for symmetrical photodetection of the electrical signals of the two detector elements. By forming the difference signal, the unwanted constant component of the intensity of the standing electromagnetic wave may be eliminated, in particular.

Furthermore, the evaluation unit may include, for example, an analog-digital converter and/or a processor for signal evaluation. For example, the signal evaluation includes a Fourier transformation of the difference signal for determining the difference frequency and thus the distance to the external object. At least part of the evaluation unit may be integrated in the substrate as an electronic circuit.

According to at least one further embodiment of the detector, an electronic circuit of the evaluation unit is integrated in the substrate. For example, the detector elements and the electronic circuit are produced in a monolithically integrated manner using a CMOS (complementary metal-oxide-semiconductor) manufacturing process. Thus, the detector includes, for example, a sequence of semiconductor layers, oxide layers and metallic layers on or in the substrate, which form the integrated electronic circuit of at least part of the evaluation unit, as well as the first detector element and the second detector element. For example, the substrate includes silicon, while the active semiconductor layers include germanium, silicon germanium or indium gallium arsenide. Furthermore, the detector elements include, for example, layers of silicon nitride, silicon oxide, silicon and/or transparent, electrically conductive oxides, which are in particular transparent for electromagnetic radiation of the wavelength λ.

According to at least one further embodiment of the detector, the substrate is transparent to electromagnetic radiation of wavelength λ and the first main surfaces of the first detector element and of the second detector element are arranged parallel to the main surface of the substrate. Electromagnetic radiation that is coupled into and/or out of the detector elements thus passes through the substrate. In particular, a large portion of electromagnetic radiation of wavelength λ, for example at least 80%, is transmitted through the substrate. In some embodiments, at least 90% is transmitted through the substrate. In some embodiments, at least 99% is transmitted through the substrate.

According to at least one further embodiment of the detector, the active semiconductor layer has a thickness which is an odd multiple of a quarter of the wavelength λ/n, where n is the average refractive index of the detector element. In other words, the thickness of the active semiconductor layer is an odd multiple of a quarter of the wavelength λ in the material of the first detector element and/or the second detector element. For example, the thickness of the active semiconductor layer is λ/(4*n), 3*λ/(4*n) or 5*λ/(4*n). In particular, the thickness of the active semiconductor layer differs significantly from a multiple of half the wavelength λ/(2*n) in the detector element. For example, the thickness of the active semiconductor layer deviates from the specified thicknesses within a tolerance of no more than ±0.25*λ/(4*n).

When the transmission signal and receiving signal are superimposed in counter-propagating directions, the photocurrent generated by the active semiconductor layer is approximately proportional to the intensity of the standing electromagnetic wave in the active semiconductor layer. In particular, the intensity of the standing electromagnetic wave is averaged over the thickness of the active semiconductor layer. An active semiconductor layer with a thickness corresponding to a multiple of half the wavelength in the material of the detector element thus averages the intensity of the standing electromagnetic wave over a full period and is therefore not suitable for determining the difference frequency. An improved signal-to-noise ratio is achieved, in particular, with a thickness of the active semiconductor layer that corresponds to the odd multiple of the quarter of the wavelength λ/n in the material of the detector element. A thickness of the active semiconductor layer that is larger than a quarter of the wavelength λ/n in the detector element does not lead, in particular, to an increased sensitivity of the detector.

A detector element may also include two or more active semiconductor layers connected in series. In this case, the active semiconductor layers in the detector element may be arranged at a distance of λ/(2*n), i.e. half the wavelength of the standing electromagnetic wave, or multiples thereof. In particular, this may improve the signal-to-noise ratio.

According to at least one further embodiment of the detector, the active semiconductor layers in the first detector element and in the second detector element are arranged parallel to each other and a distance between the active semiconductor layer in the first detector element and the active semiconductor layer in the second detector element in a direction perpendicular to a main extension plane of the active semiconductor layers is an odd multiple of a quarter of the wavelength λ/n, where n is an average refractive index of the detector elements. In particular, λ/n is the wavelength of the electromagnetic radiation in the material of the detector elements. For example, the distance between the active semiconductor layers is λ/(4*n), 3*λ/(4*n), or 5*λ/(4*n).

Thus, for example, the active semiconductor layer of the first detector element is arranged at a node of the standing electromagnetic wave, while the active semiconductor layer of the second detector element is arranged at an anti-node of the standing electromagnetic wave, or vice versa. Advantageously, this increases the signal-to-noise ratio during the differential measurement of the photocurrents.

If the active semiconductor layers are formed as pn-junctions, the distance between the active semiconductor layers is specified, for example, in relation to an interface between a p-doped semiconductor layer and an n-doped semiconductor layer of the pn-junction. Otherwise, the distance denotes, for example, a distance between centers of the active semiconductor layers in a direction perpendicular to the main extension plane of the active semiconductor layers. The distance may deviate from the specified distances within a tolerance of at most ±0.25*λ/(4*n).

According to at least one further embodiment of the detector, the substrate is formed from a semiconductor material and the active semiconductor layer includes a doped region of the main surface of the substrate. In particular, the active semiconductor layer of the first detector element and/or the second detector element is integrated in the substrate.

The detector elements may include, for example, a transparent layer or transparent layers including a dielectric material, a transparent conductive oxide, and/or an epitaxial semiconductor material. The transparent layer may be arranged on the active semiconductor layer, for example on the main surface of the substrate. In particular, the transparent layer is transparent to electromagnetic radiation of wavelength λ and has, for example, a transmittance of at least 99%.

The transparent layers of the first detector element and the second detector element may have different thicknesses. Thus, a different phase shift of the standing electromagnetic wave may be set at the position of the active semiconductor layer in the first detector element and in the second detector element. In particular, the thicknesses and/or a refractive index of the transparent layers are advantageously set such that the active semiconductor layer of the first detector element is arranged, for example, at a node of the standing electromagnetic wave, while the active semiconductor layer of the second detector element is arranged at an anti-node of the standing electromagnetic wave, or vice versa.

According to at least one further embodiment of the detector, the active semiconductor layer is part of a Schottky-contact. In particular, the active semiconductor layer forms a Schottky-contact with metallic contacts applied thereto. The active semiconductor layer may be a doped area of the substrate, wherein the substrate includes a semiconductor material or consists of a semiconductor material. For example, the detector elements are designed as MSM (metal-semiconductor-metal) photodiodes, whereby the active semiconductor layer of the MSM photodiode may be integrated in the substrate. Detector elements including MSM photodiodes may be integrated in the substrate, in particular, using the CMOS manufacturing process.

According to at least one further embodiment, the active semiconductor layers in the first detector element and in the second detector element have an equal surface area in a main extension plane of the active semiconductor layers. In particular, absorption areas for electromagnetic radiation of wavelength λ in the active semiconductor layers of the first detector element and the second detector element have the same size. By forming the difference signal between the electrical signal of the first detector element and the electrical signal of the second detector element, the unwanted constant component of the intensity of the standing electromagnetic wave is thus advantageously completely or almost completely eliminated.

Different sizes of the absorption areas in the active semiconductor layers of the first detector element and the second detector element give rise to a systematic difference in the photocurrents generated by the active semiconductor layers. Thus, the unwanted constant component of the standing electromagnetic wave is not completely eliminated by forming the difference signal. The systematic difference in the photocurrents of the first detector element and the second detector element may also be compensated for by an electronic circuit, for example in the evaluation unit.

According to at least one further embodiment of the detector, the second detector element partially or completely encloses the first detector element in a lateral direction. For example, in a plan view of the main surface of the substrate, the first detector element has a rectangular or circular cross-sectional area. The second detector element has, for example, a ring-shaped or ring-segment-shaped cross-sectional area, wherein the first detector element is arranged within the ring-shaped or ring-segment-shaped second detector element.

The cross-sectional surfaces of the detector elements may have any shape. For example, the cross-sectional areas of the detector elements may interlock like fingers. Surfaces between the detector elements may be configured at least partially as transmission windows, in particular for the transmission signal. Alternatively or additionally, integrated electronic circuits, for example of the evaluation unit, may be arranged between the detector elements.

According to at least one further embodiment of the detector, an optical path length of electromagnetic radiation of wavelength λ within the first detector element and an optical path length of electromagnetic radiation of wavelength λ within the second detector element are equal, or differ by an integer multiple of the wavelength λ. A plane electromagnetic wave that passes through the detector is thus coupled out of the two detector elements with the same phase. In particular, a wavefront of the transmission signal is therefore not distorted as it passes through the detector elements of the detector.

According to at least one further embodiment of the detector, a backside of the substrate opposite the main surface is structured such that a difference between an optical path length of electromagnetic radiation of wavelength λ within the first detector element and an optical path length of electromagnetic radiation of wavelength λ within the second detector element is equalized. For example, the substrate has different thicknesses at locations where the first detector element and the second detector element are arranged. This may compensate for the difference between the optical path lengths of the electromagnetic radiation in the detector elements as it passes through the substrate. Thus, for example, a distortion of the wavefront of the transmission signal, which occurs when passing through the detector elements, is compensated, reduced or avoided when passing through the substrate.

According to at least one further embodiment of the detector, a plurality of first and second detector elements are arranged in pairs as a two-dimensional detector array on the main surface of the substrate. For example, a plurality of first and second detector elements are arranged in pairs in the form of a regular two-dimensional grid. Alternatively, the plurality of first and second detector elements may be arranged as a one-dimensional detector array or form a one-dimensional detector array.

By arranging a plurality of first and second detector elements in a two-dimensional detector array, in particular a direction of the receiving signal may be determined in conjunction with an imaging optics. This makes a two-dimensional detector array suitable for determining the distance and direction of the external object at the same time. Furthermore, a radial velocity of the external object may be determined, for example, via a Doppler shift of the difference frequency between the transmission signal and the receiving signal.

Further, a lidar module is disclosed. In particular, the lidar module includes a detector as described herein. All features disclosed for the detector are also disclosed for the lidar module, and vice versa.

According to at least one embodiment, the lidar module includes a detector as described herein. In particular, the detector is configured for differential detection of the difference frequency between the transmission signal and the counter-propagating receiving signal.

According to at least one further embodiment, the lidar module includes a laser light source configured for generating electromagnetic laser radiation with the wavelength λ. The laser light source includes, for example, an edge-emitting laser diode, a surface-emitting laser diode, a fiber laser, a fiber-enhanced laser, a DFB laser (distributed feedback laser), or any variants thereof.

Laser light is generated by stimulated emission and, in contrast to electromagnetic radiation generated by spontaneous emission, generally includes a very high coherence length, a very narrow spectral linewidth and/or a high degree of polarization. The coherence length of the laser light source may be at least equal to or greater than twice the maximum distance between the lidar module and the external object that should still be detectable.

According to at least one further embodiment of the lidar module, at least part of the electromagnetic laser radiation generated during operation is coupled into the detector. The electromagnetic laser radiation generated during operation includes, in particular, the transmission signal, which is, for example, at least partially coupled into the first and second detector elements via the first main surface. The transmission signal may be coupled out again via the second main surface.

For example, the transmission signal generated by the laser light source traverses the detector at least partially before it is emitted from the lidar module and subsequently at least partially reflected back from the external object. The receiving signal includes the transmission signal that is at least partially reflected back from the external object and is coupled into the detector elements in counter-propagating direction to the transmission signal.

According to at least one further embodiment, the lidar module includes an imaging optics. For example, the imaging optics is configured for collimating the transmission signal. Furthermore, the imaging optics may be configured for determining the direction of the receiving signal together with the detector array.

According to at least one further embodiment of the lidar module, the laser light source includes a first radiation outcoupling surface and a second radiation outcoupling surface opposite the first radiation outcoupling surface, wherein laser radiation coupled out from the second radiation outcoupling surface during operation is coupled into the detector. The laser light source is, for example, an edge-emitting laser diode.

In particular, a large portion of the laser radiation generated during operation, for example at least 90%, is coupled out via the first radiation outcoupling surface and emitted as a transmission signal from the lidar module. The smaller portion of the laser radiation generated during operation that is coupled out via the second radiation outcoupling surface is coupled into the detector as a transmission signal and superimposed there with the counter-propagating receiving signal. In particular, the transmission signal coupled out from the lidar module does not pass through the detector. Thus, the out-coupled transmission signal is advantageously not distorted by the detector.

Further, a method for operating a lidar module is disclosed. In particular, the method is configured for operating a lidar module as described herein. All features of the lidar module are also disclosed for the method for operating a lidar module, and vice versa.

According to at least one embodiment, the method of operating a lidar module includes emitting a transmission signal including a frequency modulated electromagnetic wave generated by the laser light source. The frequency of the electromagnetic wave may be increased and/or decreased periodically and linearly as a function of time.

According to at least one further embodiment of the method for operating a lidar module, a receiving signal is received which includes the transmission signal that is at least partially reflected by an external object. The receiving signal is, for example, coupled into the detector via an imaging optics.

According to at least one further embodiment of the method for operating a lidar module, the receiving signal and at least part of the transmission signal are coupled into the detector in counter-propagating directions and are superimposed in the detector such that the standing electromagnetic wave is formed in the detector. In particular, the standing electromagnetic wave is formed in the first detector element and in the second detector element of the detector.

According to at least one further embodiment of the method for operating a lidar module, the difference frequency between the transmission signal and the receiving signal in the standing electromagnetic wave is determined from a difference signal of the detector. In particular, the standing electromagnetic wave includes a temporal oscillation at the difference frequency between the frequency of the transmission signal and the frequency of the receiving signal. The differential signal of the detector therefore oscillates at the same difference frequency, which may be determined, for example, by a Fourier transformation of the difference signal.

According to at least one further embodiment of the method for operating a lidar module, a distance to the external object is determined from the difference frequency. Due to a propagation time of the transmission signal from the lidar module to the external object and back again, the receiving signal includes a higher or lower frequency compared to the transmission signal at the time of the counter-propagating superposition with the transmission signal in the detector. With a linear modulation of the frequency of the transmission signal, the difference frequency between the transmission signal and the receiving signal in the detector is thus proportional to the propagation time and therefore proportional to the distance between the lidar module and the external object. By determining the difference frequency, for example using a fast Fourier transformation in the evaluation unit, the distance to the external object may be determined.

Further advantageous embodiments and further developments of the detector, the lidar module and the method for operating the lidar module follow from the exemplary embodiments described below in conjunction with the figures.

### BRIEF DESCRIPTION OF THE DRAWINGS

FIGS. 1 to 4 show schematic sectional views of detectors according to various non-limiting embodiments.

FIGS. 5 and 6 show schematic electronic circuits of evaluation units of a detector according to various non-limiting embodiments.

FIGS. 7 to 9 show schematic arrangements of detector elements according to various non-limiting embodiments.

FIGS. 10 and 11 show schematic sectional views of detector arrays according to various non-limiting embodiments.

FIGS. 12 and 13 show schematic views of lidar modules according to various non-limiting embodiments.

FIGS. 14 to 16 show schematic views of detectors according to various non-limiting embodiments.

FIG. 17 shows a schematic sectional view of a detector according to a non-limiting embodiment.

Elements that are identical, similar or have the same effect are marked with the same reference signs in the figures. The figures and the proportions of the elements shown in the figures are not to be regarded as true to scale. Rather, individual elements, in particular layer thicknesses, may be shown exaggeratedly large for better visualization and/or understanding.

### DETAILED DESCRIPTION

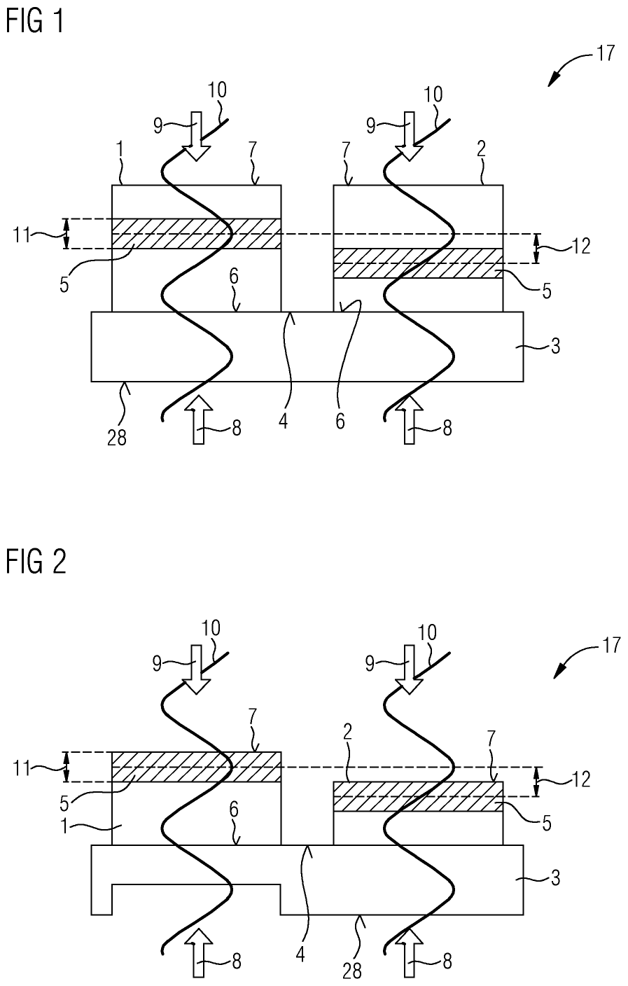

FIG. 1 shows a non-limiting embodiment of a detector 17 including a substrate 3, a first detector element 1 and a second detector element 2. The substrate 3 is made of silicon and is transparent to electromagnetic radiation of wavelength λ. The first detector element 1 and the second detector element 2 are arranged laterally next to each other on a main surface 4 of the substrate 3 and include the same geometric dimensions. In particular, both lateral expansions and an expansion in a direction perpendicular to the main surface 4 of the substrate 3 of the two detector elements 1, 2 are the same within manufacturing tolerances.

The two detector elements 1, 2 include a first main surface 6 and a second main surface 7 opposite the first main surface 6, which are each configured for coupling in and for coupling out electromagnetic radiation of wavelength λ. The first main surfaces 6 of the two detector elements 1, 2 face the main surface 4 of the substrate 3 and are aligned parallel thereto. The two detector elements 1, 2 are formed from materials or include materials that are transparent to electromagnetic radiation of wavelength λ. In particular, the materials include a transmissivity of at least 90%. For example, the detector elements 1, 2 may include silicon, silicon nitride and/or silicon oxide.

During operation of the detector 17, a transmission signal 8 including electromagnetic laser radiation of wavelength λ is coupled into the detector 17 via a backside 28 of the substrate 3 opposite the main surface 4 and further coupled into the first detector element 1 and the second detector element 2 via the first main surfaces 6. After passing through the two detector elements 1, 2, the transmission signal 8 is coupled out, in particular via the second main surfaces 7, and emitted in the direction of an external object 21. A receiving signal 9, which includes at least a part of the transmission signal 8 reflected back from the external object 21, is coupled into the two detector elements 1, 2 via the second main surfaces 7 and superimposed there with the transmission signal 8 in the counter-propagating direction. In particular, a standing electromagnetic wave 10 is formed in the two detector elements 1, 2. Alternatively, the transmission signal 8 may also be coupled in via the second main surfaces 7, while the receiving signal 9 is coupled into the detector 17 via the backside 28 of the substrate 3.

The first detector element 1 and the second detector element 2 each include an active semiconductor layer 5, which is configured for converting electromagnetic radiation of wavelength λ into an electrical signal. The active semiconductor layer 5 is arranged between the first main surface 6 and the second main surface 7 of the detector element 1, 2. A thickness 11 of the active semiconductor layer 5 may be a quarter of the wavelength of the standing electromagnetic wave 10 in a material of the detector elements 1, 2, i.e. λ/(4*n), where n denotes an average refractive index of the material of the detector elements 1, 2. In particular, the thickness 11 of the active semiconductor layer 5 differs significantly from multiples of half the wavelength λ/(2*n).

In particular, the active semiconductor layers 5 are arranged such that the active semiconductor layer 5 in the first detector element 1 is located, for example, at an anti-node of the standing electromagnetic wave 10, while the active semiconductor layer 5 in the second detector element 2 is arranged at a node of the standing electromagnetic wave 10, or vice versa. A distance 12 between the active semiconductor layers 5 in the first detector element 1 and in the second detector element 2 is thus an odd multiple of a quarter of the wavelength of the standing electromagnetic wave 10 in the material of the detector elements 1, 2. For detector elements 1, 2 with an average refractive index n, the distance 12 is thus an odd multiple of λ/(4*n), for example λ/(4*n), 3*λ/(4*n), or 5*λ/(4*n).

The detector 17 is configured for a differential detection of a difference frequency between a frequency of the transmission signal 8 and a frequency of the receiving signal 9, from which in particular a distance 29 to the external object 21 may be determined. The standing electromagnetic wave 10 includes a temporal oscillation with the difference frequency, which may be determined with an improved signal-to-noise ratio by the arrangement of the active semiconductor layers 5 in the first detector element 1 and in the second detector element 2 as described above. In particular, by forming a difference signal between the electrical signal of the first detector element 1 and the electrical signal of the second detector element 2, an unwanted constant background signal caused by an unwanted constant component of an intensity of the standing electromagnetic wave 10 may be reduced or eliminated.

The first detector element 1 and the second detector element 2 have the same spatial extension between the first main surface 6 and the second main surface 7. Thus, a wavefront of the transmission signal 8 is advantageously not or only slightly distorted when passing through the detector elements 1, 2. The detector elements 1, 2 may have an optical path length between the first main surface 6 and the second main surface 7 that corresponds to an integer multiple of the wavelength λ. As a result, the transmission signal 8 has the same phase after passing through the detector elements 1, 2 as a part of the transmission signal 8 that does not pass through the detector elements 1, 2. Thus, a wavefront of the transmission signal 8 is advantageously not or only slightly distorted as it passes through the detector 17.

FIG. 2 shows a further non-limiting embodiment of a detector 17. In contrast to the detector 17 in FIG. 1, the active semiconductor layers 5 in the first detector element 1 and in the second detector element 2 are directly adjacent to the second main surfaces 7. The thicknesses 11 of the active semiconductor layers 5 and a distance 12 between the active semiconductor layers 5 in the first detector element 1 and in the second detector element 2 are formed analogously to the non-limiting embodiment of FIG. 1. Thus, the first detector element 1 and the second detector element 2 include a different spatial extension in the direction perpendicular to the main surface 4 of the substrate 3.

Due to the different spatial extension of the two detector elements 1, 2, the optical path length of the transmission signal 8 in the first detector element 1 differs from the optical path length of the transmission signal 8 in the second detector element 2. In FIG. 2, the first detector element 1 includes a larger spatial extension and thus a larger optical path length of the transmission signal 8. To compensate for this difference, the backside 28 of the substrate 3 is structured. In particular, the substrate 3 has a smaller thickness at a point where the first detector element 1 is arranged. This compensates for the different optical path lengths of the transmission signal 8 in the two detector elements 1, 2 as the transmission signal 8 passes through the substrate 3.

FIG. 3 shows a non-limiting embodiment of a detector 17 which is structurally identical to the detector 17 FIG. 1. The active semiconductor layers 5 of the detector 17 of FIG. 3 are formed as photodiodes and include in particular a pn-junction consisting of an n-doped semiconductor layer 13 and a p-doped semiconductor layer 14. Here, the n-doped semiconductor layer 13 of the pn-junction is facing the substrate 3. Alternatively, the p-doped semiconductor layer 14 of the pn-junction may also face the substrate 3. The detector 17 may be produced using a CMOS process in silicon technology, with the active semiconductor layers 5 including doped silicon germanium or doped germanium. The substrate 3 may additionally include an electronic circuit of a part of an evaluation unit 26. The detector 17 with the optoelectronic detector elements 1, 2 and the electronic circuit is thus produced in an integrated manner using a low-cost CMOS process.

FIG. 4 shows a further non-limiting embodiment of a detector 17. In contrast to FIG. 3, the pn-junctions in the first detector element 1 and in the second detector element 2 are arranged in the same way, but include a different doping profile. In particular, the first detector element 1 has a thicker n-doped semiconductor layer 13, while the second detector element 2 has a thicker p-doped semiconductor layer 14. In particular, the active semiconductor layers 5 are space-charge regions at an interface between the n-doped semiconductor layer 13 and the p-doped semiconductor layer 14. The distance 12 between the active semiconductor layers 5 in the first detector element 1 and in the second detector element 2 is the same as in the detectors 17 of FIGS. 1 and 3.

The different doping profiles in the first detector element 1 and in the second detector element 2 are produced, for example, by ion implantation. A sufficiently small thickness of the space-charge region and thus of the active semiconductor layer 5 in the detector elements 1, 2 is achieved by high doping and a low diffusion length of a dopant outside the space-charge region. The detector 17 shown in FIG. 4 may be advantageously produced with a smaller number of process steps compared to the detector in FIG. 3.

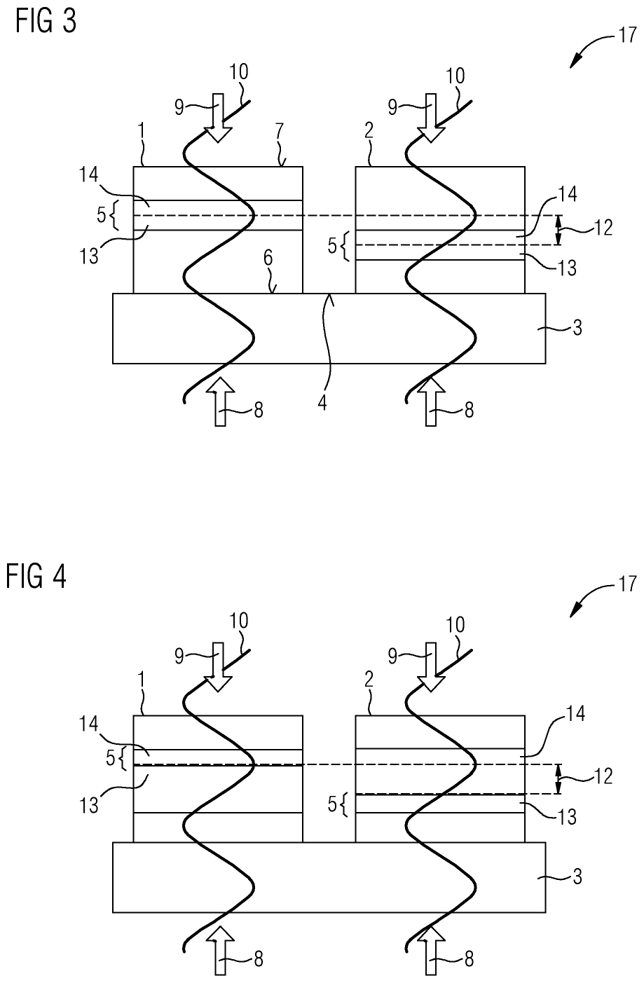

FIG. 5 shows a schematic electronic circuit of a differential amplifier of a non-limiting embodiment, which forms at least part of an evaluation unit 26 of the detector 17. In particular, the differential amplifier is configured for subtracting photocurrents of the active semiconductor layers 5 of the first detector element 1 and the second detector element 2, thereby at least partially eliminating the unwanted constant component of the intensity of the standing electromagnetic wave 10. The output of the differential amplifier thus provides an electrical voltage that oscillates in time with the difference frequency between the frequency of the transmission signal 8 and the frequency of the receiving signal 9. The amplification of the photocurrents of the two detector elements 1, 2 may be adjusted separately, whereby a systematic difference in intensity of the standing electromagnetic wave 10 in the two detector elements 1, 2 may be compensated. The electronic circuit may be integrated into the substrate 3 by a CMOS manufacturing process using silicon technology.

FIG. 6 shows a schematic electronic circuit of a non-limiting embodiment for symmetrical photodetection as part of an evaluation unit 26 of a detector 17. The electronic circuit shown here converts a difference between the photocurrents of the two detector elements 1, 2 with a transimpedance amplifier into an electrical output voltage which in particular oscillates in time with the difference frequency between transmission signal 8 and receiving signal 9.

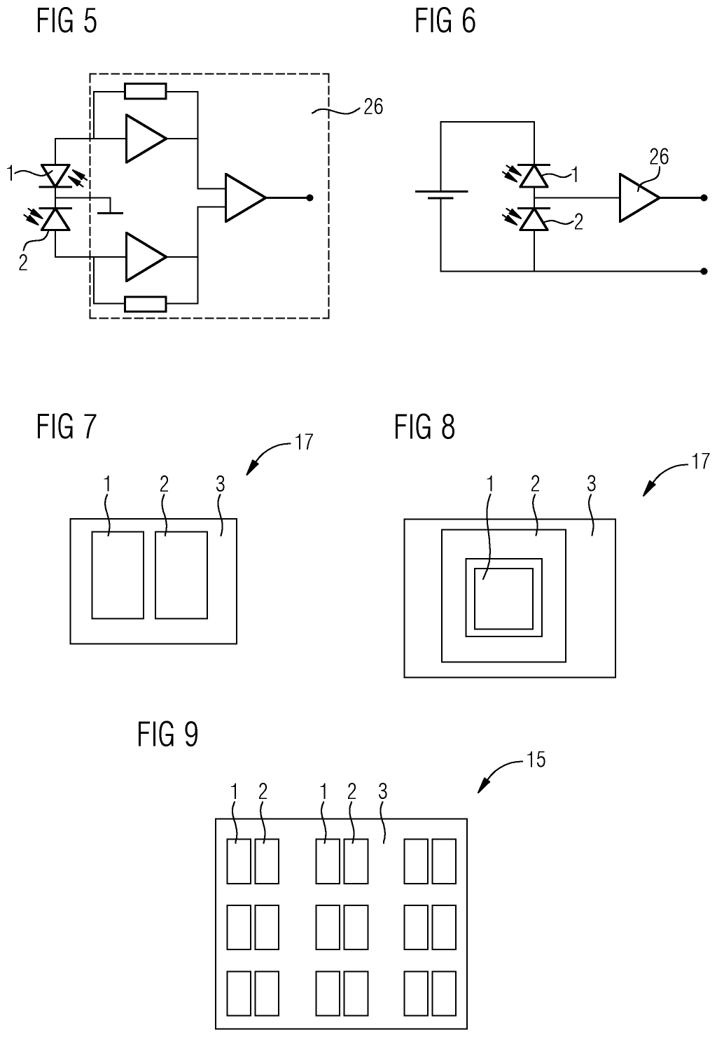

FIG. 7 shows a non-limiting embodiment detector 17 in plan view of the main surface 4 of the substrate 3. The first detector element 1 and the second detector element 2 have the same cross-sectional area and are arranged laterally next to each other. In particular, the arrangement of the detector elements 1, 2 corresponds to the non-limiting embodiments of FIGS. 1 to 4.

FIG. 8 shows a further non-limiting embodiment of a detector 17 in plan view of the main surface 4 of the substrate 3. In contrast to FIG. 7, the second detector element 2 include a ring-shaped cross-sectional area and completely encloses the first detector element 1 in the lateral direction.

FIG. 9 shows a schematic arrangement of a non-limiting embodiment of a plurality of detector elements 1, 2 in a detector array 15 in plan view of the main surface 4 of the substrate 3. In particular, first detector elements 1 and second detector elements 2 are arranged pairwise next to each other in the form of a regular rectangular grid as a two-dimensional detector array 15. The difference between the electrical signals of the first and second detector elements 1, 2 arranged directly next to each other may be formed during operation. In particular, the detector array 15 is configured for detecting a distance 29 to an external object 21 and, in conjunction with an imaging optics, simultaneously a direction of the external object 21.

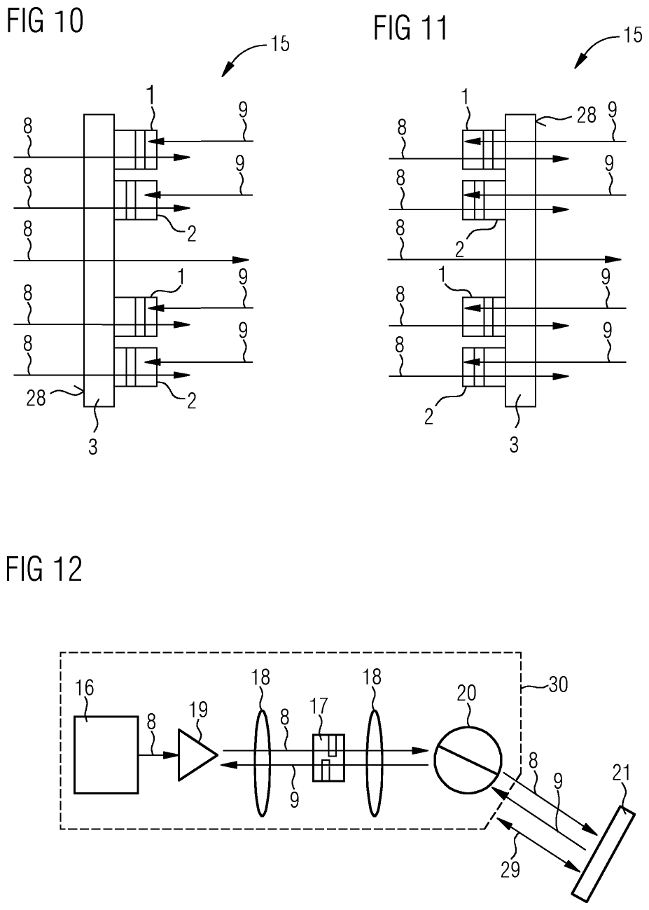

FIG. 10 shows a non-limiting embodiment of a detector 17, which, in particular, is formed as a detector array 15 with a plurality of first and second detector elements 1, 2. Here, the transmission signal 8 is coupled into the detector array 15 and in particular into the detector elements 1, 2 via the backside 28 of the substrate 3. A part of the transmission signal 8 is radiated past the detector elements 1, 2 in the direction of the external object 21. This advantageously increases the illumination intensity at the external object. This may be particularly advantageous compared to a larger detection area of the detector array 15, as otherwise there are high requirements for parallelism of the beam paths of the receiving signal 9. In particular, the receiving signal 9 should overlap coherently with the transmission signal 8 over the entire area of the detector array 15. If the portion of the transmission signal 8 transmitted through the detector elements 1, 2 is large, then the thickness of the detector elements 1, 2 is advantageously adapted such that the portion of the transmission signal 8 transmitted through the detector elements 1, 2 is in phase with the portion of the transmission signal 8 that is radiated past the detector elements 1, 2.

FIG. 11 shows a further non-limiting embodiment of a detector array 15 with a plurality of first and second detector elements 1, 2. Here, in contrast to FIG. 10, the transmission signal 8 is coupled out of the detector array 15 via the backside 28 of the substrate 3, while the receiving signal 9 is coupled into the detector array 15 via the backside 28 of the substrate 3.

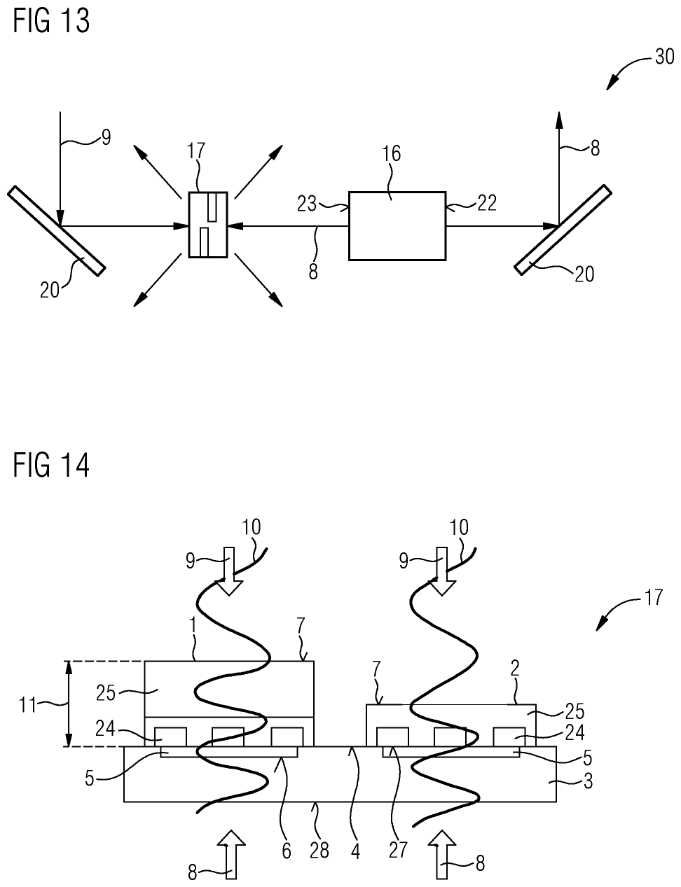

FIG. 12 shows a schematic structure of a lidar module 30 of a non-limiting embodiment including a laser light source 16 and a detector 17. In operation, the transmission signal 8 is generated by the laser light source 16 and coupled into the detector 17 via an optical isolator 19 and an imaging optics 18. After passing through the detector 17, the transmission signal 8 is coupled out from the lidar module 20 via a further imaging optics 18 and a beam deflecting element 20 and emitted in the direction of an external object 21. The external object 21 has a distance 29 that is to be determined from the lidar module 30. Part of the transmission signal 8 is reflected by the external object 21 and coupled back into the lidar module 30 as receiving signal 9, where it is superimposed with the counter-propagating transmission signal 8 in the detector 17. In particular, the optical isolator 19 prevents the receiving signal 9 from being coupled back into the laser light source 16 and forming an unwanted interference there.

For example, the frequency of the transmission signal 8 is increased linearly as a function of time. Thus, at the time of superposition with the receiving signal 9 in the detector 17, the transmission signal 8 has, for example, a higher frequency than the receiving signal 9 due to a transit time of the transmission signal 8 from the lidar module 30 to the external object 21 and back. In particular, the distance 29 to the external object 21 may be determined from the difference frequency between the transmission signal 8 and the receiving signal 9.

FIG. 13 shows a further non-limiting embodiment of a lidar module 30 of a non-limiting embodiment, wherein the laser light source 16 includes a first radiation outcoupling surface 22 and a second radiation outcoupling surface 23 opposite the first radiation outcoupling surface 22. The laser light source 16 is, for example, an edge-emitting laser diode. In particular, a large part of the laser radiation generated during operation, for example at least 90%, is coupled out from the lidar module 30 via the first radiation outcoupling surface 22 and a beam deflecting element 20 and emitted as a transmission signal 8 in the direction of the external object 21.

The receiving signal 9 is superimposed with a part of the counter-propagating transmission signal 8 in the detector 17, whereby this part of the transmission signal 8 is coupled out from the laser light source 16 via the second radiation outcoupling surface 23 and coupled directly into the detector 17. Thus, the transmission signal 8 coupled out from the lidar module 30 does not pass through the detector 17 and is therefore advantageously not distorted.

The detector 17 advantageously includes detector elements 1, 2 that interlock like fingers and thus diffract a portion of the transmission signal 8 and/or the receiving signal 9 transmitted through the detector 17. As a result, feedback of the receiving signal 9 into the laser light source 16 and thus unwanted interference in the laser light source 16 may be avoided.

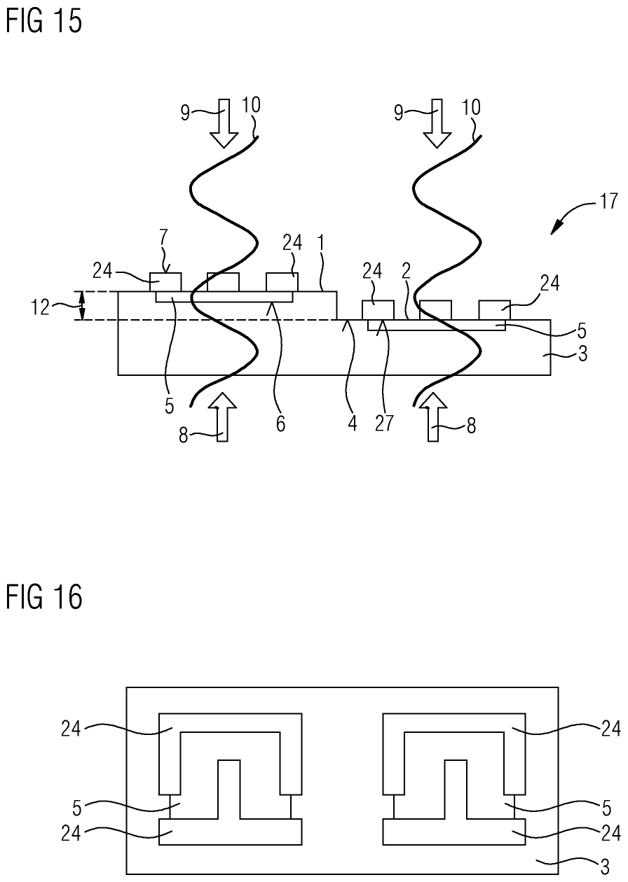

FIG. 14 shows a schematic sectional view of non-limiting embodiment of a detector 17, in which the first detector element 1 and the second detector element 2 are designed as MSM photodiodes, in contrast to the detector 17 in FIG. 3. The MSM photodiodes include Schottky-contacts 27 between metallic contacts 24 on the substrate 3 and active semiconductor layers 5 in the substrate 3. In particular, the active semiconductor layers 5 of the two detector elements 1, 2 are formed as doped regions of the main surface 4 of the substrate 3. The active semiconductor layers 5 include, in particular, silicon germanium and have a thickness that is less than half the wavelength in the detector material λ/(2*n). The thickness of the active semiconductor layers 5 may be a quarter of the wavelength in the detector material λ/(4*n) and may be adjusted, for example, by an implantation depth of a dopant in the substrate 3.

In order to achieve a phase difference of the standing electromagnetic wave 10 at the positions of the active semiconductor layers 5 in the first detector element 1 and in the second detector element 2, the detector elements 1, 2 include a transparent layer 25 which is applied to the main surface 4 of the substrate 3. In particular, the transparent layer is arranged on the active semiconductor layer 5 and on the metallic contacts 24 of the respective detector element 1, 2. The transparent layer 25 has a larger thickness 11 in the first detector element 1 than in the second detector element 2, or vice versa. The transparent layer 25 includes, for example, a dielectric material, a transparent conductive oxide, and/or an epitaxial semiconductor material, or consists of one of these materials.

The thicknesses 11 of the transparent layers 25 in the first detector element 1 and in the second detector element 2 are set such that a phase difference of the standing electromagnetic wave 10 at the positions of the active semiconductor layers 5 of the two detector elements 1, 2 is an odd multiple of π/2. For example, an anti-node of the standing electromagnetic wave 10 is arranged in the active semiconductor layer 5 of the first detector element 1, while a node of the standing electromagnetic wave 10 is arranged in the active semiconductor layer 5 of the second detector element 2, or vice versa.

It is also possible that only one detector element includes a transparent layer 25. Analogous to the non-limiting embodiment of FIG. 2, the backside 28 of the substrate 3 may be structured in order to compensate for a different optical path length of the transmission signal 8 in transparent layers 25 of the two detector elements 1, 2.

FIG. 15 shows a further non-limiting embodiment of a detector 17, in which the first detector element 1 and the second detector element 2 are designed as MSM photodiodes. In contrast to the detector of FIG. 14, no transparent layer 25 is applied to the substrate 3 in order to generate a phase difference of the standing electromagnetic wave 10 in the two detector elements 1, 2. Instead, the main surface 4 of the substrate is structured so that a distance 12 between the active semiconductor layers 5 in the first detector element 1 and in the second detector element 2 is an odd multiple of a quarter of the wavelength λ in the material of the substrate. For example, the structuring of the substrate 3 is produced by etching the main surface 4.

FIG. 16 shows a schematic view of a detector 17 according to the non-limiting embodiments of FIGS. 14 and 15 in a plan view of the main surface 4 of the substrate 3. In particular, a non-limiting structure of the metallic contacts 24 of the MSM photodiodes is shown, with two metallic contacts 24 interlocking in a finger-like manner in each case. Alternatively, the metallic contacts 24 may be formed as concentric structures, for example.

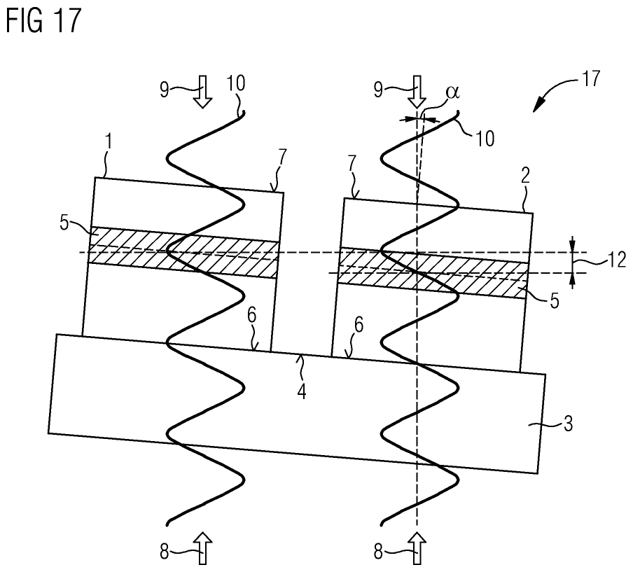

FIG. 17 shows a detector 17 according to a further non-limiting embodiment. In contrast to the detector 17 described in connection with FIG. 1, the first detector element 1 and the second detector element 2 may be of the same design as the non-limiting embodiment according to FIG. 17. In particular, the active semiconductor layers 5 in the first detector element 1 and in the second detector element 2 are formed at the same position between the first main surface 6 and the second main surface 7. In other words, the distance between the first main surface 6 and the active semiconductor layer 5, and/or the distance between the second main surface 7 and the active semiconductor layer 5, is the same in the first detector element 1 and in the second detector element 2, at least within the limits of manufacturing tolerances.

In order for a phase difference of the standing electromagnetic wave 10 between the positions of the active semiconductor layers 5 of the first detector element 1 and the second detector element 2 to be an odd multiple of π/2, the main surface 4 of the substrate 3 is inclined relative to a propagation direction of the standing electromagnetic wave 10. In other words, the transmission signal 8 and the receiving signal 9 are incident on the first and second main surfaces 6, 7 of the first and second detector elements 1, 2 at an angle of incidence a, wherein the angle of incidence a is different from 0°. Here, the angle of incidence a denotes an angle between the propagation direction of the transmission signal 8 or the receiving signal 9 and the surface normal of the first and/or second main surfaces 6, 7. In particular, a distance 12 between the active semiconductor layers 5 of the first and second detector elements 1, 2 in the propagation direction of the standing electromagnetic wave 10 may be a quarter of the wavelength of the electromagnetic radiation in the material of the detector elements 1, 2.

The present disclosure is not limited to the non-limiting embodiments by the description thereof. Rather, the present disclosure includes any combination of features, even if the combination itself is not explicitly stated in the patent claims or non-limiting embodiments.

### LIST OF REFERENCE SYMBOLS

1 first detector element
2 second detector element
3 substrate
4 main surface
5 active semiconductor layer
6 first main surface
7 second main surface
8 transmission signal
9 receiving signal
10 standing electromagnetic wave
11 thickness
12 distance
13 n-doped semiconductor layer
14 p-doped semiconductor layer
15 detector array
16 laser light source
17 detector
18 imaging optics
19 optical isolator
20 beam deflecting element
21 external object
22 first radiation outcoupling surface
23 second radiation outcoupling surface
24 metallic contact
25 transparent layer
26 evaluation unit
27 Schottky contact
28 backside
29 distance
30 lidar module
α angle of incidence

1. A detector comprising:
a substrate; and
at least a first detector element and a second detector element, which are arranged laterally next to one another on a main surface of the substrate, wherein
each of the detector elements comprises an active semiconductor layer configured for converting electromagnetic radiation having a wavelength λ into an electrical signal,
each of the detector elements comprises a first main surface and a second main surface opposite the first main surface, and
the first main surface and the second main surface are each configured for coupling in and for coupling out electromagnetic radiation of wavelength λ, and
the detector is configured for forming a difference signal between the electrical signal of the first detector element and the electrical signal of the second detector element.

2. The detector according to claim 1, further comprising:
an evaluation unit, wherein
the evaluation unit is configured for forming a difference signal between the electrical signal of the first detector element and the electrical signal of the second detector element.

3. The detector according to claim 2, wherein an electronic circuit of the evaluation unit is integrated in the substrate.

4. The detector according to claim 1, wherein the substrate is transparent to electromagnetic radiation of wavelength λ, and the first main surfaces of the first detector element and of the second detector element are arranged parallel to the main surface of the substrate.

5. The detector according to claim 1, wherein the active semiconductor layer has a thickness which is an odd multiple of a quarter of the wavelength λ/n, where n is an average refractive index of the detector element.

6. The detector according to claim 1, wherein
the active semiconductor layers in the first detector element and in the second detector element are arranged parallel to each other, and
a distance between the active semiconductor layer in the first detector element and the active semiconductor layer in the second detector element in a direction perpendicular to a main extension plane of the active semiconductor layers is an odd multiple of a quarter of the wavelength λ/n, where n is an average refractive index of the detector elements.

7. The detector according to claim 1, wherein the substrate is formed from a semiconductor material and the active semiconductor layer comprises a doped region of the main surface of the substrate.

8. The detector according to claim 1, wherein the active semiconductor layer is part of a Schottky-contact.

9. The detector according to claim 1, wherein the active semiconductor layers in the first detector element and in the second detector element have an equal surface area in a main extension plane of the active semiconductor layers.

10. The detector according to claim 1, wherein the second detector element partially or completely encloses the first detector element in a lateral direction.

11. The detector according to claim 1, wherein an optical path length of electromagnetic radiation of wavelength λ within the first detector element and an optical path length of electromagnetic radiation of wavelength λ within the second detector element are equal, or differ by an integer multiple of the wavelength λ.

12. The detector according to claim 1, wherein a backside of the substrate opposite the main surface is structured such that a difference between an optical path length of electromagnetic radiation of wavelength λ within the first detector element and an optical path length of electromagnetic radiation of wavelength λ within the second detector element is equalized.

13. The detector according to claim 1, wherein a plurality of first detector elements and second detector elements are arranged in pairs as a two-dimensional detector array on the main surface of the substrate.

14. A lidar module comprising:
at least one detector according to claim 1; and
a laser light source configured for generating electromagnetic laser radiation with the wavelength λ, wherein
at least part of the electromagnetic laser radiation generated during operation is coupled into the detector.

15. The lidar module according to claim 14, wherein the laser light source comprises a first radiation outcoupling surface and a second radiation outcoupling surface opposite the first radiation outcoupling surface, wherein laser radiation coupled out from the second radiation outcoupling surface during operation is coupled into the detector.

16. A method of operating a lidar module according to claim 14, the method comprising the steps of:
emitting a transmission signal comprising a frequency modulated electromagnetic wave generated by the laser light source;
receiving a receiving signal comprising the transmission signal that is at least partially reflected by an external object, wherein the receiving signal and at least part of the transmission signal are coupled into the detector in counter-propagating directions and are superimposed in the detector such that a standing electromagnetic wave is formed in the detector;
determining a difference frequency between the transmission signal and receiving signal in the standing electromagnetic wave from a difference signal of the detector; and
determining a distance to the external object from the difference frequency.
